(19) United States
(12) Patent Application Publication
(10) Pub. No.: US 2008/0007157 A1
(43) Pub. Date: Jan. 10, 2008

(54) Compound of nanostructures and polymer for use in electroluminescent device

(75) Inventors: David L. Carroll, Winston-Salem, NC (US); Sakutaro Hoshi, Aichi (JP)

Correspondence Address: SUGHRUE-265550, 2100 PENNSYLVANIA AVE. NW, WASHINGTON, DC, 20037-3213, US

(73) Assignee: Yazaki Corporation

(21) Appl. No.: 11/482,998

(22) Filed: Jul. 10, 2006

(51) Int. Cl. H01L 51/54; H01L 51/56; H01B 1/00; H01B 1/24

(52) U.S. Cl. 313/504; 428/323; 428/367; 428/398; 428/690; 428/917; 313/506; 427/66; 257/E51.032; 257/E51.04; 252/510

(57) ABSTRACT

A compound for use in an electroluminescent device, including 0.001% to 10% by weight of nanostructure and a polyfluorene polymer. The compound can be used as a light emitting layer of an EL device including a cathode, an anode, and the light emitting layer disposed between the cathode and the anode. The EL device can be manufactured by providing a substrate, providing an anode or cathode on the substrate, and depositing the emitting layer on the substrate. The compound can be manufactured by ultrasonically cutting nanostructures and mixing the nanostructures with a polymer, such as the polyfluorene polymer.

### FIELD OF THE INVENTION

The present invention relates to electroluminescent (EL) devices, such as self-light-emitting elements. More particularly, the present invention relates to the materials used in EL devices.

### BACKGROUND OF THE INVENTION

EL devices can be used as light sources for flat-type self-light-emitting display devices for purposes. For example, flat-type self-light-emitting elements can be used in automotive instrument display panels. In general, an EL device is a spontaneously luminous element characterized by injecting electrons and electron holes (i.e., carriers) into an inorganic or organic layer provided between electrodes, and recombining the electrons and electron holes in a luminous layer. Light is produced when the electrons and electron holes recombine.

Although EL devices have achieved some practical use, there is room for improvement with respect to driving voltage requirements, useful life, brightness or luminous efficiency, and manufacturing techniques. Luminous efficiency is the ratio of an amount of input current to an amount of output light. For example, if the current input to the EL device (i.e., the carriers) are all converted into visible light, an internal efficiency is 100%. However, because some of the recombining of holes and electrons actually takes place outside of the luminous layer, many of the carriers are converted into thermal vibrations or energy other than visible light. Thus, the internal efficiency for most EL devices is actually around several percent.

EL devices are broadly divided into two types: inorganic and organic. The main causes of deterioration in an organic EL device are penetration into, and attachment to, the organic luminous layer by active molecules of water and changes in the properties of the organic luminous layer. In order to address these problems, EL devices have been developed in which a light emitting polymer is doped with carbon nanostructures.

Doping the emitting layer of EL devices with carbon nanostructures provides several advantages. First, doping carbon nanostructures into the layers of EL devices can reduce the required driving voltage. For example, because carbon nanostructures have excellent electrical conductivity, when they are doped into the layers of the EL device, the required driving voltage for the EL device as a whole is reduced. Also, because carbon nanostructures are not degraded in the presence of water (e.g., they maintain their electrical conductivity), carbon nanotubes can reduce the degradation of the electrical conductivity of the EL device as a whole.

Second, doping carbon nanostructures into the layers of EL devices can lead to a longer useful life for the EL device. For example, because carbon nanostructures reduce the required driving voltage have excellent electrical conductivity, the nanostructures reduce the amount of resistance heating within the EL device. This increases the device's lifespan. Also, due to the increased electrical conductivity, the films that make up the EL device can be made thicker. Thicker films have better resistance to water penetration, and therefore degradation of the EL devices.

Third, doping nanostructures into the layers of EL devices can enhance the brightness of the EL devices. For example, because of the excellent electrical conductivity of carbon nanostructures, the nanostructures have a homogenizing effect on the conductivity of the EL device as a whole. This homogenized conductivity improves the brightness of the EL device.

Further, carbon nanostructures act as hole trapping elements so, when they are present in the EL device (especially in the emitting layer), they increase the luminous efficiency by causing greater re-combination of holes and electrons in the luminous layer. That is, without carbon nanostructures in the emitting layer, the supply of electrons to the emitting layer is inhibited due to a low recombination frequency with respect to positive holes in the luminescent layer. If the holes travel too quickly through the luminescent layer, positive holes are leaked into the cathode side. This results in recombination outside the luminescent layer. When too many positive holes accumulate near the cathode, the supply of electrons to the luminescent layer is reduced. However, when carbon nanostructures are doped into the EL device, especially the emitting layer, the recombination frequency of the EL device is improved by slowing the traveling speed of the holes through the luminescent layer and/or by increasing the supply of electrons to the emitting layer because of a decrease in the leakage of positive holes to the cathode side. This controlled carrier mobility leads to better device performance. More specifically, the present invention achieves a higher luminance and external efficiency due to enhanced recombination dynamics.

Fourth, doping carbon nanostructures into the layers of EL devices leads to simplified manufacturing techniques. Because the carbon nanostructure-doped films in the EL devices can be made thicker, as described above, the films are easier to produce and can be produced with less costly processes.

Although doping carbon nanostructures into the layers of EL devices has many advantages, if the carbon nanostructures aggregate, they can lead to current leaks. Such current leaks degrade the performance of the EL device as a whole. Therefore, the nanostructures are preferably uniformly dispersed throughout the emitting layer of the EL device.

U.S. Pat. No. 6,833,201, which is incorporated herein by reference, discloses EL devices in which the emitting layer includes a derivative of poly(phenylene-vinylene) (PPV) doped with carbon nanostructures. However, the lifetime and performance of these EL devices is limited. Accordingly, there is a need to improve the lifetime and performance of EL devices by using an emitting layer with a different organic polymer doped with nanostructures.

### SUMMARY OF THE INVENTION

A first aspect of the invention is a compound for use in an electroluminescent device, including 0.001% to 10% by weight of nanostructure and a polyfluorene polymer.

A second aspect of the invention is an EL device including a cathode, an anode, and a light emitting layer disposed between the cathode and the anode, whereby he light emitting layer is the compound discussed above.

A third aspect of the invention is a method of making an EL device, including providing a substrate including a cathode or anode, depositing a layer of a compound including a polymer and nanostructure on the substrate, and disposing a cathode or anode on the compound.

### BRIEF DESCRIPTION OF THE DRAWINGS

The advantages, nature and various additional features of the invention will appear more fully upon consideration of the exemplary embodiment of the invention which is schematically set forth in the drawings, in which:

FIG. 1 shows chemical structures of examples of PFO polymers suitable for use as a host material of a light emitting compound according to an exemplary embodiment of the invention.

FIG. 2 is an EL device according to an exemplary embodiment.

FIG. 3 is a flowchart of the process of fabrication of the EL device according to the exemplary embodiment.

FIGS. 4A and 4B show an anode positioned on a substrate.

FIG. 5 is a flowchart of cleaning of the combined anode and glass substrate.

FIG. 6 is a flowchart of coating of a buffer layer on the combined substrate and anode.

FIG. 7 is a flowchart of coating of a light emitting layer on the buffer layer.

FIG. 8 is a flowchart of removing metal catalysts from the single wall carbon nanotubes.

FIG. 9 is a flowchart of cutting the single wall carbon nanotubes cut to an appropriate length.

FIG. 10 is a flowchart of preparation of the emitting compound of PFO polymer and nanostructures.

FIG. 11 is a flowchart of depositing a cathode layer on the emitting layer.

### DETAILED DESCRIPTION OF THE REPRESENTATIVE EMBODIMENTS

It is to be understood by one of ordinary skill in the art that the present discussion is a description of exemplary embodiments only, and is not intended as limiting the broader aspects of the present invention, which broader aspects are embodied in the exemplary construction.

### Light Emitting Compound

A light emitting material according to an exemplary embodiment of the invention is a compound of a polyfluorene (PFO) polymer host material doped with nanostructures. The compound can be used as an emitting layer of an EL device.

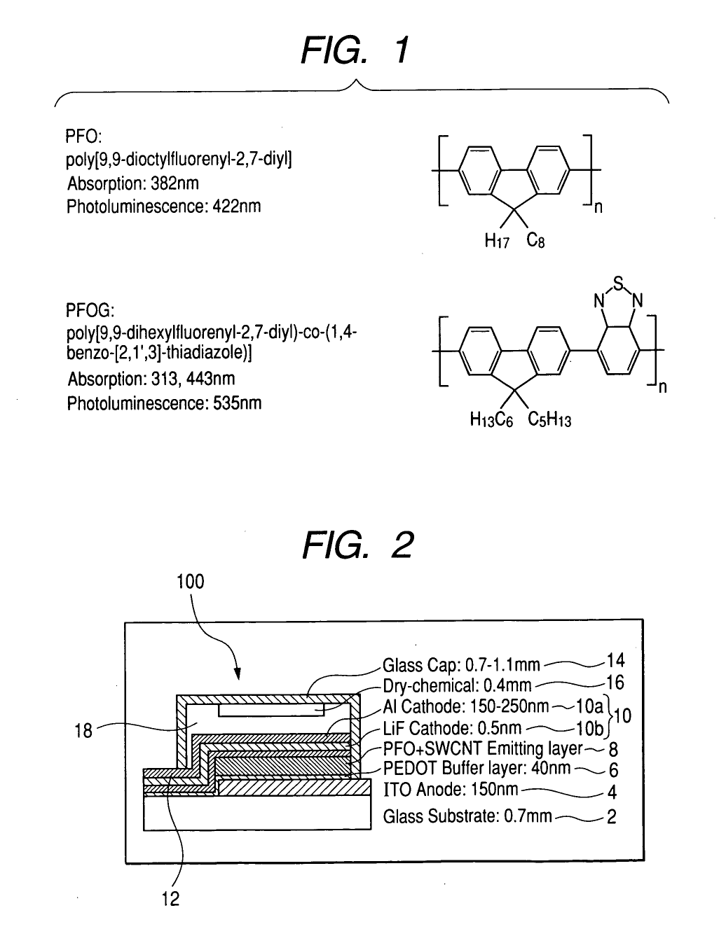

Examples of PFO polymers suitable for use as the host material are PFOG, PFOR, and PFOB. Specifically, PFO: poly[9,9-diocytlfluorenyl-2,7-diyl], which has an absorption of 382 nm and a photoluminescence at 422 nm and PFOG: poly[9,9-dihexylfluorenyl-2,7-diyl]-co-(1,4,-benzo-[2,1′,3]-thadizole)], which has an absorption of 313 nm or 443 nm and a photoluminescence at 535 nm, are suitable structures. However, the invention is not limited in this respect. The chemical structures for these polymers are shown in FIG. 1.

EL devices using PFO polymers have increased performance and increased lifetime in comparison with EL devices using PPV polymers. That is, the PFO polymers have a favorable HOMO-LUMO (highest occupied molecular orbital-lowest unoccupied molecular orbital) gap compared with PPV polymers.

Examples of suitable nanostructures are provided below. The nanostructures typically are carbon nanostructures, such as single-wall carbon nanotubes (SWCNT) or multi-walled carbon nanotubes (MWCNT). The carbon nanotubes can be short or long. Carbon nanostructures include both structures that are purely carbon, i.e., fullerenes, and structures that are doped.

Some examples of suitable fullerenes include carbon cluster compounds represented by C₆₀, C₇₀, C₇₆, C₇₈, C₈₂, C₈₄, C₉₀, C₉₆, and C₁₄₀, for example. In addition, some examples of suitable doped structures are carbon nanostructures doped with, for example, boron (B) or nitrogen (N). B-doped carbon nanotubes and N-doped carbon nanotubes can be used to better match the energy levels of a polymer with the ionized potential (IP) of the nanotube. Finally, instead of carbon nanostructures other nanostructures, such boron-nitride nanostructures (e.g., nanotubes), can be used.

The amount of nanostructures that are doped into a layer of an EL device can vary somewhat. However, if too many nanostructures are doped into the layers including the glass substrate to the luminescent layer, the nanostructures will optically inhibit the luminous efficiency of the EL device because the nanostructures absorb light. On the other hand, if there are not enough nanostructures, there will not be a sufficient hole trapping effect so that luminous efficiency of the EL device will not be improved.

Additionally, the amount of the nanostructures may vary depending on the type of nanostructure and on the luminescent color of the EL device.

For example, fullerenes in solution have an absorption wavelength with peaks changing between seven different colors as the fullerene changes from C₆₀ to C₁₄₀. Thus, an appropriate fullerene and amount thereof depend on the desired color of EL emission. Further, there is a proper amount of nanostructures with respect to their electrical effect on the EL device. That is, since the band gap differs among luminescent materials having different luminescent colors, the optimum amount of nanostructure dopant for enhancing the EL device's electrical characteristic will vary depending on the luminescent color.

Preferably, the concentration of nanostructures within the emitting compound is between 0.001 to 10% by weight. Moreover, it has been observed that using 30 to 500 nm SWNT works well. For example, a tested example of the emitting compound, which is discussed below, included dopant carbon nanotubes with a length of about 500 nm. However, the invention is not limited to the tested examples, and other types of nanostructures, such as the nanostructures discussed above, can be used.

### EL Device

An EL device 100 according to an exemplary embodiment of the invention is shown in FIG. 2. The EL device 100 includes a glass substrate 2 and an anode 4 disposed on the glass substrate 2. A buffer layer 6 is disposed on the anode 4, and an emitting layer 8 is disposed on the buffer layer 6. Further, a cathode 10 is disposed on the emitting layer 8. A glass cap 14 surrounds the buffer layer 6, emitting layer 8, and cathode 10. A chamber 18 is formed around these layers. A dry chemical layer 16 is provided on the underside of the glass cap 14 at the top of this chamber 18.

Examples of the materials for parts of the EL device 100 other than the emitting layer 8 are as follows. The anode 4 may be an iridium titanium oxide (ITO) layer. The buffer layer 6 may include polyethylenedioxythiophene (PEDOT). If the buffer layer 6 is a PEDOT layer, the buffer layer 6 also acts as a hole transportation layer. However, a separate buffer layer and a separate hole transportation layer can also be used. The cathode 10 may be a layer 10b of lithium fluoride (LiF) and an aluminum layer 10a disposed on the LiF layer 10b. The dry chemical layer 16 may be silicon or another desiccant. Although specific materials have been described for the layers of the EL device, these materials are merely exemplary, and any other suitable material may be substituted therefore. As for the emitting layer 8, its composition can vary according to the description for the compound as set forth above.

The glass cap 14 is supported on the anode 4 and the cathode 10 by a sealant 12. The glass cap 14 forms the chamber 18 around the layers 6, 8, and 10 of the EL device 100. During operation of the EL device, a potential 20 is connected between the anode 4 and the cathode 14 so as to cause light L to be emitted from the EL device. During operation of the EL device, a cooling gas G, such as N₂ may be introduced into the chamber 18. This cooling gas G cools the EL device.

### Fabrication of the EL Device

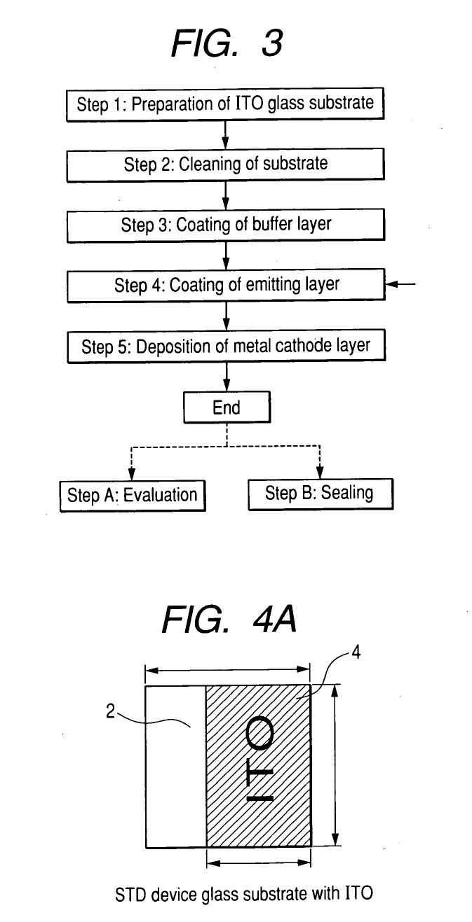

The fabrication of an EL device according to the exemplary embodiment of the invention is described below. As shown in flowchart of FIG. 3, first the glass substrate 2 with anode 4 is prepared (Step 1), then the substrate is cleaned (Step 2) and the buffer layer 6 is coated on the substrate 2 and anode 4 (Step 3), an emitting layer 8 is coated on the buffer layer 6 (Step 4), and a cathode 10 is deposited on the emitting layer 8 (Step 5). The manufactured EL device is then evaluated (Step A) and sealed (Step B) with the gas cap 14, or another sealant.

Details of an exemplary embodiment of the preparation of the EL device are provided below. The glass substrate 2 and anode 4 are prepared by providing a 25.4 mm (1 inch)×25.4 mm×0.7 mm thick glass substrate of soda-lime glass. The glass 2 is pre-polished so that its surface roughness is less than 5 nm.

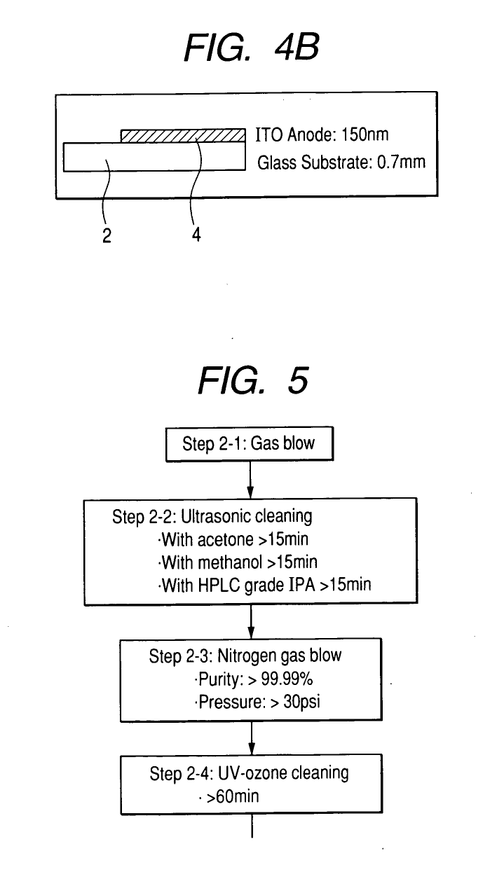

Then an anode 4 of ITO is provided on the glass substrate 2. The anode is 25.4 mm×15.9 mm×150 nm. The anode 4 is positioned on the substrate as shown in FIGS. 4A and 4B. The anode is polished so that its surface roughness is less than 3 nm. The electrical resistance of the anode is less than 10 ohm/m. The transparency of the combined anode and glass is greater than 95% at a frequency of 555 nm.

Next, the combined anode and glass substrate is cleaned in the manner shown in FIG. 5. First, in step 2-1, nitrogen (N₂) gas is blown on the combined anode and cathode before ultrasonic cleaning is performed. The combined anode and glass is provided within a glass dish that is filled with various solvents.

Then, in step 2-2, the glass dish is provided within an ultrasonic cleaning device, and ultrasonic cleaning is performed. Ultrasonic cleaning is performed for 15 minutes with acetone as the solvent, for 15 additional minutes with methanol as the solvent, and then for 15 minutes with High Performance Liquid Chromatography (HPLC) grade Isopropyl alcohol (IPA).

Then, in Step 2-3, a stream of nitrogen gas is used to dry the substrates after the IPA cleaning. The nitrogen gas has a purity of 99.99% and a pressure of 30 psi. Finally in Step 2-4, the combined substrate and anode is placed with the anode face up on a UV-Ozone cleaner. A UV-Ozone cleaning is performed for 60 minutes.

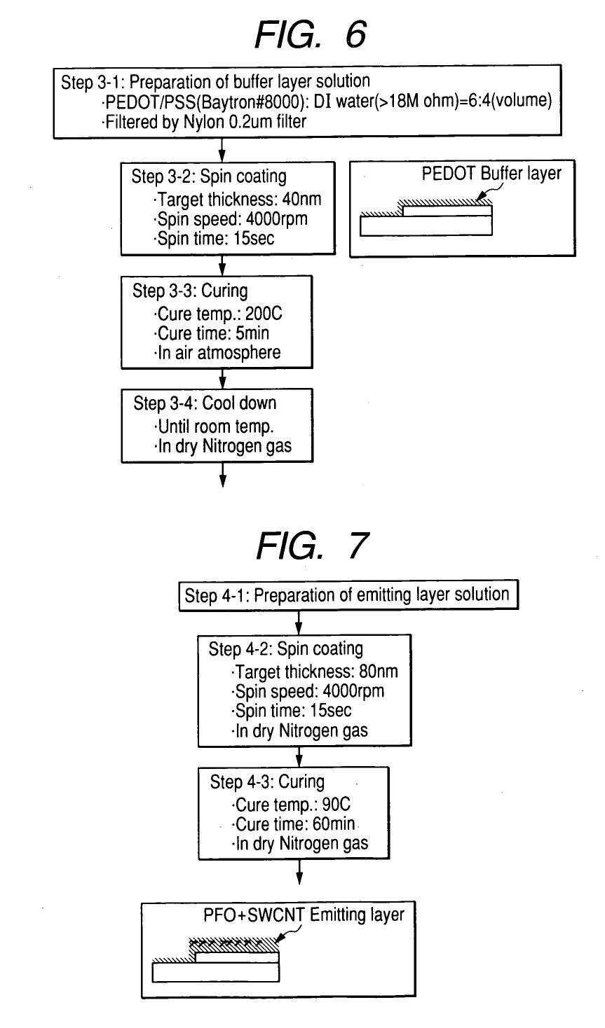

Next, the buffer layer 8 is coated on the combined substrate and anode in the manner shown in FIG. 6. First, in Step 3-1, a buffer layer solution of 6 parts per volume of PEDOT, poly(3,4-ethylenedioxythiophene):poly(styrene sulfate) (PSS) (e.g., Baytron #8000), and 4 parts per volume of de-ionized water (e.g., greater than 18M ohm). The buffer layer solution is filtered by a nylon syringe filter with 0.2 micrometer pores.

Then, in Step 3-2, the buffer layer is spin coated on the combined substrate and anode until the layer has a thickness of 40 nm. The spin speed is 4000 rpm and the spin time is 15 seconds.

In Step 3-3, the substrate and anode coated with the buffer layer is provided in a petri dish 62 and cured on a hotplate at a temperature of 200 degrees C for 5 minutes at atmospheric pressure. The substrate and anode coated with the buffer layer is then annealed in a desiccator.

Finally, in Step 3-4, the substrate and anode coated with the buffer layer is cooled with dry nitrogen gas until the substrate and anode coated with the buffer layer reached room temperature.

Then, the emitting layer is coated on the buffer layer 6 as shown in the flowchart of FIG. 7. First, in Step 4-1, the emitting layer solution is prepared.

Then, in Step 4-2, the emitting layer solution is spin coated on the previously formed buffer layer until the emitting layer has a thickness of 80 nm. Again, the spin speed is 4000 rpm and the spin time is 15 seconds. The spin coating takes place in an environment of nitrogen.

In Step 4-3, the substrate, which now includes the coated emitting layer, is provided in a petri dish and cured on a hotplate at a temperature of 90 C for 60 minutes in an environment of nitrogen.

The tested exemplary embodiment of the emitting layer is a compound of PFO polymer and 0.1% by weight SWCNT. In order to produce this compound, first, the SWCNT are purified. The purification of the SWCNT includes removing metal catalysts from a root material of Hydrogen-Bonded and Physisorbed Carbon Monoxide (HiPco) SWCNT and controlling the length of the SWCNT. The use of pure HiPco SWCNT root material increases the performance of the emitting layer.

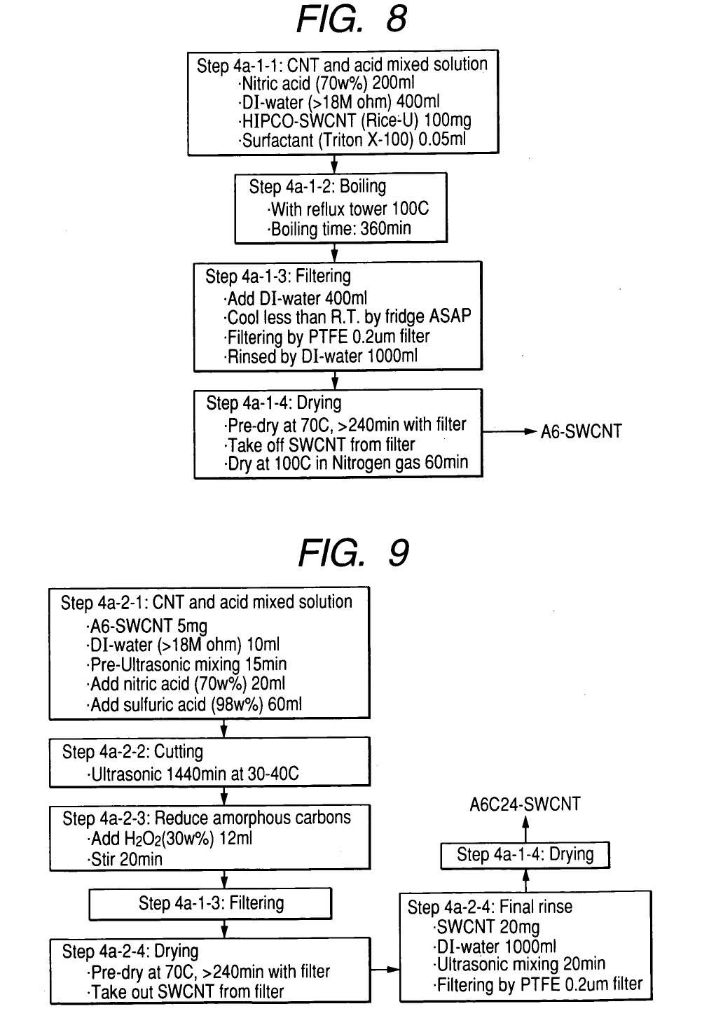

FIG. 8 is a flowchart of the process of removing metal catalysts from the root material. First, in Step 4a-1-1, the SWCNT are mixed within an acid solution. The SWCNT-acid solution includes 200 ml of a solution that is 70% by weight nitric acid, 400 ml of de-ionized water (e.g., greater than 18M ohm), 100 mg of HiPco SWCNT, and 0.05 ml of a surfactant (e.g., Triton X-100).

Then, in Step 4a-1-2, a flask of the SWCNT-acid solution is boiled within a reflux tower for 6 hours (“A6”).

Then, in Step 4a-1-3, 400 ml of de-ionized water is added to the solution, and the solution is provided within a refrigeration unit as soon as possible. The solution is cooled to room temperature. Then, the cooled solution is filtered by a vacuum filtration unit having a polytetrafluoroethylene (PTFE) (e.g., TEFLON) filter with 0.2 micrometer pores to produces a mat of purified SWCNT, or buckypaper. Then, the mat of SWCNT is rinsed by 1000 ml of de-ionized water.

Finally, in Step 4a-1-4, the mat of SWCNT is dried. The mat of SWCNT is pre-dryed for 240 minutes at a temperature of 70 degrees C. while still within the filter of the vacuum filtration unit. Then, the mat of A6-SWCNT is removed from the filter and dried at 100 degrees C. for 60 minutes.

Next, the purified A6-SWCNT are cut to the appropriate length. FIG. 9 is a flowchart of this process. In step 4a-2-1, the SWCNT are mixed in another acid solution. First, 5 mg of A6-SWCNT and 10 ml of de-ionized water (e.g., greater than 18M ohm) are mixed together. Then, the A6-SWCNT-water is mixed with 20 ml of nitric acid (e.g., 70% by weight) and 60 ml of sulfuric acid (e.g., 98% by weight).

In step 4a-2-2, the SWCNT are cut ultrasonically for 12 hours (“24 C”) at 30-40 degrees C. If the SWCNT are subjected to ultrasonic vibrations for a longer time and/or are subjected to higher power ultrasonic vibrations, then the lengths of the SWCNT are reduced. A flask of the SWCNT-acid solution is continuously cooled by a water flow during the cutting process.

Then, in Step 4a-2-3, the amount of amorphous carbon in the SWCNT-acid solution is reduced. The SWCNT solution is transferred to a flat bottom flask on a stirplate. Twelve ml of H₂O₂ (30% by weight) is added to the bottom of the stirred solution. The solution and H₂O₂ are stirred for 20 minutes.

In Step 4a-1-3, the solution and H₂O₂ are filtered.

In Step 4a-2-4, the SWNT are pre-dried for 240 minutes or more at a temperature of 70 degrees C. while still within the filter.

In Step 4a-2-5, 20 mg of SWCNT are mixed ultrasonically with 1000 ml of de-ionized water for 20 minutes. The SWCNT are filtered by a PTFE filter with 0.2 micrometer pores.

Finally, in Step 4a-1-4, the purified A6C24-SWCNT are dried.

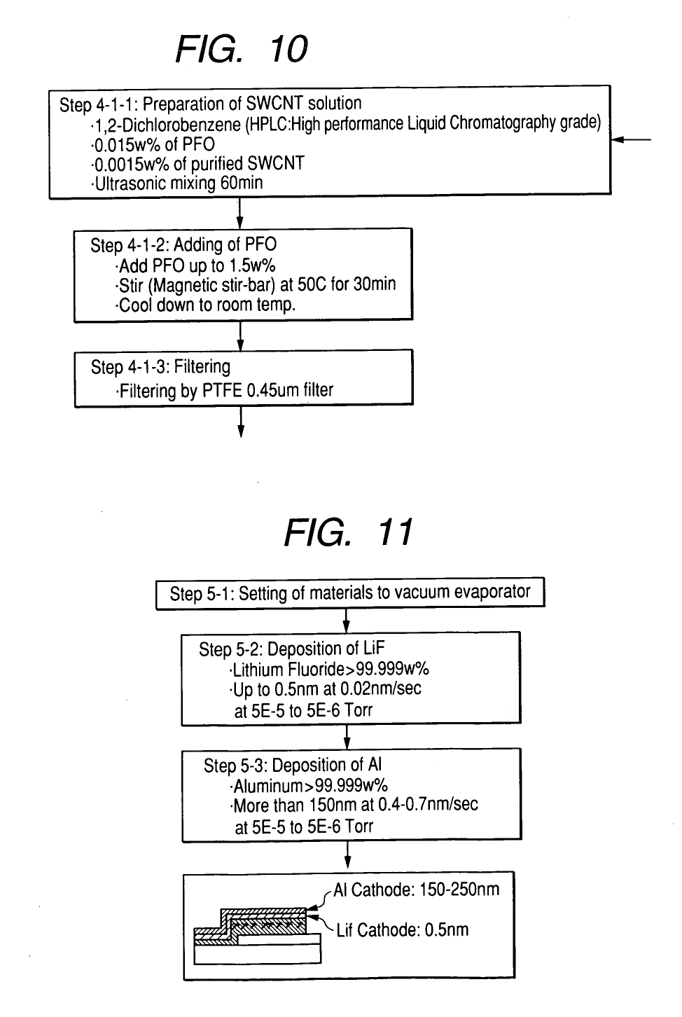

FIG. 10 is a flowchart of the preparation of the emitting compound of PFO polymer and nanostructures. First, in Step 4-1-1, a SWCNT solution is produced from the purified A6C24-SWCNT. The solution includes HPLC grade 1,2-Dichlorobenzene (DCB), 0.015% by weight PFO, and 0.0015% by weight purified SWCNT. The solution is mixed for 60 minutes.

Then, in Step 4-1-2, another solution including 1.5% by weight PFO polymer is added. The mixture is stirred with a magnetic stir bar at 50 degrees C. for 30 minutes, and then cooled to room temperature.

Then, in Step 4-1-3, the mixture is filtered by a PTFE filter with 0.45 micrometer pores. The final emitting compound includes PFO polymer and SWCNT. The DCB evaporates and, therefore, is not part of the final compound. Note that the final compound can also include dyes, such as Alq3 (tris(8-hydroxyquinolinato)aluminum), porphorines, or heavy metal chelates, and/or any combination of nanoparticles, such as quantum dots.

FIG. 11 is a flowchart of the process of depositing a metal cathode layer on the emitting layer. In step 5-1, Lithium Fluoride (LiF) (e.g., greater than 99.999% by weight) and Aluminum (Al) (e.g., greater than 99.999% by weight) are set in a vacuum evaporator. These materials can be provided sequentially in the same vacuum evaporator or provided in separate vacuum evaporators.

Then, in Step 5-2, a layer of LiF is deposited on the emitting layer at a thickness of up to 0.5 nm at a deposition rate of 0.02 nm/s at a pressure of 5×10⁻⁵ to 5×10⁻⁶ Torr.

Then, in Step 5-3, a layer of Al is deposited on the emitting layer at a thickness of more than 150 nm at a deposition rate of 0.7-0.7 nm/s at a pressure of 5×10⁻⁵ to 5×10⁻⁶ Torr.

Once the cathode layer has been provided on the emitting layer, the EL device is ready for evaluation.

### Evaluation of the ET Device

The manufactured EL device is evaluated with respect to both IVL (current/voltage/luminescence) and VLT (visible light transmission). The value of IVL is derived from the current, voltage, and brightness properties of the EL device. The quantities of current injection, maximum brightness, emitting efficiency, and power efficiency can be derived from the IVL value. The value of VLT is a lifetime measurement of the continuance driving properties of the EL device. The VLT value is derived by measuring the applied voltage and emitting brightness for a constant current. The VLT value is measured at room temperature in a nitrogen rich environment (i.e., low moisture and oxygen).

Testing of the manufactured EL devices showed that, for the most part, maximum brightness, emitting efficiency, and power efficiency improved for each of PFOG, PFOR, and PFOB doped with SWCNT when compared with the IVL value for un-doped PFOG, PFOR, and PFOB, respectively.

In addition, PFOG doped with SWCNT that was oxidized resisted failure better than un-doped PFOG that was oxidized. That is, the oxidized un-doped PFOG had significantly reduced current injection, emitting efficiency, and power efficiency compared with un-oxidized PFOG, while the oxidized doped PFOG did not have significant reductions in these areas. This resistance to oxidation results in a longer lifetime for PFO doped with SWCNT.

These and other modifications and variations of the present invention may be practiced by those of ordinary skill in the art, without departing from the spirit and scope of the present invention, which is set forth in the appended claims. In addition, it should be understood that aspects of the various embodiments may be interchanged both in whole or in part. Furthermore, those of ordinary skill in the art will appreciate that the foregoing description is by way of example only, and is not intended to limit the invention so further described in the claims.

We claim:

1. A compound for use in an electroluminescenit device, the compound comprising:
0.001% to 10% by weight of nanostructure; and
a polyfluorene polymer.

2. The compound of claim 1, wherein the nanostructure includes a carbon nanostructure.

3. The compound of claim 2, wherein the carbon nanostructure includes a carbon nanotube.

4. The compound of claim 1, wherein an amount of the nanostructure is about 0.1% by weight of the compound.

5. The compound of claim 4, wherein an amount of the polyfluorene polymer is about 1.5% by weight of the compound.

6. The compound of claim 5, wherein a length of the nanostructure is 30 to 500 nm.

7. The compound of claim 6, wherein the length of the nanostructure is about 500 nm.

8. The compound of claim 3, wherein the carbon nanotube includes a single-walled nanotube.

9. The compound of claim 1, wherein the polyfluorene polymer includes at least one of PFOG, PFOR, and PFOB.

10. An electroluminescent device comprising:
a cathode;
an anode; and
a light emitting layer disposed between the cathode and the anode, wherein the light emitting layer comprises the compound set forth in claim 1.

11. The electroluminescent device of claim 10, further comprising a substrate, wherein one of the anode and the cathode is provided on the substrate.

12. The electroluminescent device of claim 11, further comprising a buffer layer disposed between the one of the cathode and anode and the light emitting layer.

13. A method of making the electroluminescent device, comprising:
providing a substrate;
providing an anode or cathode on the substrate;
providing a light emitting layer on the anode or cathode, wherein the light emitting layer is the compound of claim 1; and
providing another cathode or anode on the light emitting layer.

14. The method of making an electroluminescent device of claim 13,
further comprising providing a buffer layer on the anode or cathode,
wherein the step of providing the light emitting layer on the anode or cathode comprises providing the light emitting layer on the buffer layer.

15. The method of making an electroluminescent device of claim 13, wherein the step of providing the light emitting layer comprises:
providing a solution of an acid and the nanostructure,
ultrasonically cutting the nanostructure, and
mixing the cut nanostructure and the polyfluorene polymer.

16. The method of making an electroluminescent device of claim 14, wherein the step of providing the light emitting layer comprises:
providing a solution of an acid and the nanostructure,
ultrasonically cutting the nanostructure, and
mixing the cut nanostructure and the polyfluorene polymer.

17. A method of making an electroluminescent device, comprising:
providing a light emitting layer by
providing a solution of an acid and a nanostructure,
ultrasonically cutting the nanostructure, and
mixing the cut nanostructure and a polymer;
providing an anode or cathode; and
providing a layer of the light emitting layer on the anode or cathode.

18. The method of making an electroluminescent device of claim 17, further comprising providing the anode or cathode on a substrate.

19. The method of making an electroluminescent device of claim 18, further comprising providing a buffer layer on the anode or cathode, wherein providing the light emitting layer on the anode or cathode comprises providing the emitting layer on the buffer layer.

20. The method of claim 17, wherein the nanostructure comprises a carbon nanostructure.
